(19) United States
(12) Patent Application Publication
(10) Pub. No.: US 2009/0104756 A1
(43) Pub. Date: Apr. 23, 2009

(54) METHOD TO FORM A REWRITEABLE MEMORY CELL COMPRISING A DIODE AND A RESISTIVITY-SWITCHING GROWN OXIDE

(76) Inventor: TANMAY KUMAR, Pleasanton, CA (US)

Correspondence Address: DUGAN & DUGAN, PC, 245 Saw Mill River Road, Suite 309, Hawthorne, NY, 10532, US

(21) Appl. No.: 11/772,081

(22) Filed: Jun. 29, 2007

(51) Int. Cl. H01L 21/00

(52) U.S. Cl. 438/482; 257/E21.001

(57) ABSTRACT

A method is described to form a rewriteable memory cell including a diode and an oxide layer, wherein the resistivity of the oxide layer can be reversibly switched. In preferred embodiments, the oxide layer is a grown oxide. The diode is preferably formed of polysilicon which has been crystallized in contact with a silicide which has a close lattice match to silicon. The silicide provides a crystallization template such that the polysilicon is large-grained with few defects, and thus relatively low-resistivity. In preferred embodiments, a monolithic three dimensional memory array can be formed, in which multiple memory levels of such rewriteable memory cells are monolithically formed vertically stacked above a substrate.

### RELATED APPLICATIONS

This application is related to Schricker et al., U.S. patent application Ser. No. ______, “Memory Cell That Employs a Selectively Grown Reversible Resistance-Switching Element and Methods of Forming the Same,” (atty. docket no. SD-MD-335×); to Schricker et al., U.S. patent application Ser. No. ______, “Memory Cell That Employs a Selectively Grown Reversible Resistance-Switching Element and Methods of Forming the Same,” (atty. docket no. SD-MD-335Y); to Schricker et al., U.S. patent application Ser. No. ______, “Memory Cell That Employs a Selectively Deposited Reversible Resistance-Switching Element and Methods of Forming the Same,” (atty. docket no. SD-MD-333×); and to Schricker et al., U.S. patent application Ser. No. ______, “Memory Cell That Employs a Selectively Deposited Reversible Resistance-Switching Element and Methods of Forming the Same,” (atty. docket no. SD-MD-333Y), all owned by the assignee of the present invention and all hereby incorporated by reference, and all filed on even date herewith.

### BACKGROUND OF THE INVENTION

A diode can be paired with a dielectric rupture antifuse to form a one-time-programmable nonvolatile memory cell having two data states. Similarly, a diode can be paired with a reversible resistivity-switching element to form a rewriteable nonvolatile memory cell. Use of known resistivity-switching materials, such as chalcogenides, can present fabrication challenges, however.

It would be advantageous to form a memory cell comprising a diode formed in series with a resistivity-switching element, wherein fabrication of the resistivity-switching element is easily integrated into the process of forming the memory cell.

### SUMMARY OF THE PREFERRED EMBODIMENTS

The present invention is defined by the following claims, and nothing in this section should be taken as a limitation on those claims. In general, the invention is directed to a rewriteable memory cell formed by pairing a switching oxide layer with a diode. Preferably the switching oxide layer is a grown oxide.

A first aspect of the invention provides for a method for forming a rewriteable memory cell, the method comprising: forming a vertically oriented diode; and thermally growing an oxide layer, wherein the diode and the grown oxide layer are disposed electrically in series between a first conductor and a second conductor, wherein the memory cell comprises the diode and the grown oxide, and wherein the grown oxide layer serves as a reversible switching element.

A preferred embodiment of the invention provides for a method for forming a monolithic three dimensional memory array, the method comprising: a) monolithically forming a first memory level above a substrate by a method comprising: i) forming a plurality of bottom conductors; ii) forming a plurality of top conductors; iii) forming a plurality of vertically oriented diodes; and iv) growing a plurality of oxide layers, wherein the first memory level comprises a first plurality of memory cells, wherein each memory cell comprises one of the diodes and one of the grown oxide layers disposed electrically in series between one of the bottom conductors and one of the top conductors, wherein, for each memory cell, the grown oxide layer serves as a reversible switching element; and b) monolithically forming a second memory level above the first.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a perspective view showing an embodiment of a memory cell described in U.S. Pat. No. 6,952,030.

FIG. 2 is a perspective view of a portion of a first memory level of memory cells like those pictured in FIG. 1.

FIG. 3 is a cross-sectional view of a memory cell formed according to a preferred embodiment of the present invention.

FIGS. 4a-4d are cross-sectional views showing stages in fabrication of a first memory level comprising memory cells formed according to a preferred embodiment of the present invention.

FIG. 5 is a probability plot showing current at a read voltage of about 2 volts for various data states of a population of memory cells formed according to the present invention.

### DETAILED DESCRIPTION OF THE PREFERRED EMBODIMENTS

FIG. 1 shows an embodiment of a memory cell described in Herner et al., U.S. Pat. No. 6,952,030, “High-density three-dimensional memory cell,” hereinafter the '030 patent. In this nonvolatile memory cell, pillar 300, comprising a diode 302 and a dielectric rupture antifuse 18, is disposed electrically in series between top conductor 400 and bottom conductor 200. In the initial state of this memory cell, when a read voltage of, for example, about 2 volts, is applied between top conductor 400 and bottom conductor 200, very little current flows between them. Application of a relatively large programming voltage between top conductor 400 and bottom conductor 200 permanently alters the memory cell of FIG. 1 so that, after programming, significantly more current flows at the same read voltage. This difference in current under the same applied read voltage allows a programmed cell to be distinguished from an unprogrammed cell; for example for a data “0” to be distinguished from a data “1”.

As described in detail in Herner et al., U.S. patent application Ser. No. 10/955,549, “Nonvolatile Memory Cell Without a Dielectric Antifuse Having High- and Low-Impedance States,” filed Sep. 29, 2004 and hereinafter the '549 application; and in Herner et al., U.S. patent application Ser. No. 11/148,530, “Nonvolatile Memory Cell Operating by Increasing Order in Polycrystalline Semiconductor Material,” filed Jun. 8, 2005, and hereinafter the '530 application, both owned by the assignee of the present invention and hereby incorporated by reference, diode 302 is formed of semiconductor material which, in the initial, unprogrammed device, is in a relatively high-resistivity state. Application of a programming voltage across diode 302 changes the semiconductor material from a high-resistivity state to a lower-resistivity state.

In a cell like that shown in FIG. 1, the programming voltage must perform two tasks. It must convert the semiconductor material of diode 302 from a high-resistivity to a low-resistivity state, and must also cause the dielectric material of dielectric rupture antifuse 18 to undergo dielectric breakdown, during which at least one conductive path is permanently formed through dielectric rupture antifuse 18.

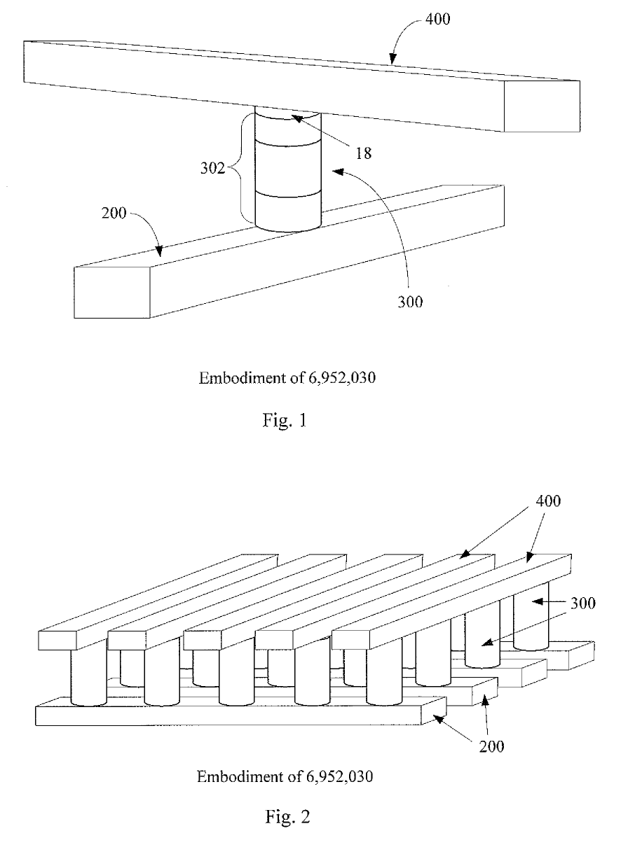

FIG. 2 shows a portion of a first memory level of cells like those of FIG. 1 arranged in a cross-point array comprising a plurality of memory cells. Each memory cell comprises a pillar 300 (which comprises the diode 302 and antifuse 18 shown in FIG. 1) disposed between one of top conductors 400 and one of bottom conductors 200. Top conductors 400 are above bottom conductors 200 and extend in a different direction, preferably perpendicular to them. Two, three, or more such memory levels can be vertically stacked atop one another, forming a monolithic three dimensional memory array.

In Herner, U.S. Pat. No. 7,176,064, “Memory Cell Comprising a Semiconductor Junction Diode Crystallized Adjacent to a Silicide,” hereinafter the '064 patent and hereby incorporated by reference, a dielectric rupture antifuse is paired with a semiconductor diode formed of semiconductor material, for example silicon, where the semiconductor material of the diode is in a low-resistivity state as formed, and need not be converted.

The diode of the '030 patent and the '549 application is formed by depositing a semiconductor material such as silicon in an amorphous state, then performing a thermal anneal to crystallize the silicon, forming a polycrystalline silicon or polysilicon diode. As described in the '530 application, when deposited amorphous silicon is crystallized in contact solely with materials with which it has a high lattice mismatch, such as silicon dioxide and titanium nitride, the polysilicon forms with a high number of crystalline defects, causing it to be high-resistivity. Application of a programming pulse through this high-defect polysilicon apparently alters the polysilicon, causing it to be lower-resistivity.

It has been found, however, that when deposited amorphous silicon is crystallized in contact with a layer of an appropriate silicide, for example titanium silicide or cobalt silicide, the resulting crystallized silicon is much higher quality, with fewer defects, and has lower resistivity. The lattice spacing of titanium silicide or cobalt silicide is very close to that of silicon, and it is believed that when amorphous silicon is crystallized in contact with a layer of an appropriate silicide at a favorable orientation, the silicide provides a template for crystal growth of silicon, minimizing defects. Unlike the high-defect silicon crystallized adjacent only to materials with which it has a high lattice mismatch, application of a large electrical pulse does not appreciably change the resistivity of this low-defect, low-resistivity silicon crystallized in contact with the silicide layer.

In the present invention a diode formed of low-defect, low-resistivity semiconductor material is paired with an oxide layer, where the oxide layer is preferably grown, for example thermally grown. The oxide layer is formed in an initial insulating or high-resistivity state. Application of an appropriate electrical pulse converts the oxide layer to a low-resistivity state. Application of an additional electrical pulse converts the oxide layer to a higher-resistivity state. The oxide layer can be reversibly switched between higher- and lower-resistivity states, forming a rewriteable memory cell.

An electrical pulse that switches the oxide layer from a higher-resistivity state to a lower-resistivity state will be called a set pulse. An electrical pulse that switches the oxide layer from a lower-resistivity state to a higher-resistivity state will be called a reset pulse. The term pulse here refers to an electrical pulse, and can be used to refer to applied voltage, to current, or both. This description will similarly refer to a set voltage or to a reset current as appropriate.

It is preferred to grow the oxide rather than to deposit it because a grown oxide is generally denser and of higher quality than a deposited oxide. Further, an oxide can be grown in an easily integrable oxidation step, for example by thermal oxidation. By pairing this switchable oxide layer with a diode formed of low-defect, low-resistivity semiconductor material, the amplitude of the electrical pulse may be only the amplitude required to switch the resistivity of the oxide layer. The semiconductor material of the diode is already in the low-resistivity state as formed, and thus need not be converted. The amplitude of the set and reset pulses may thus be reduced and made more controllable and predictable.

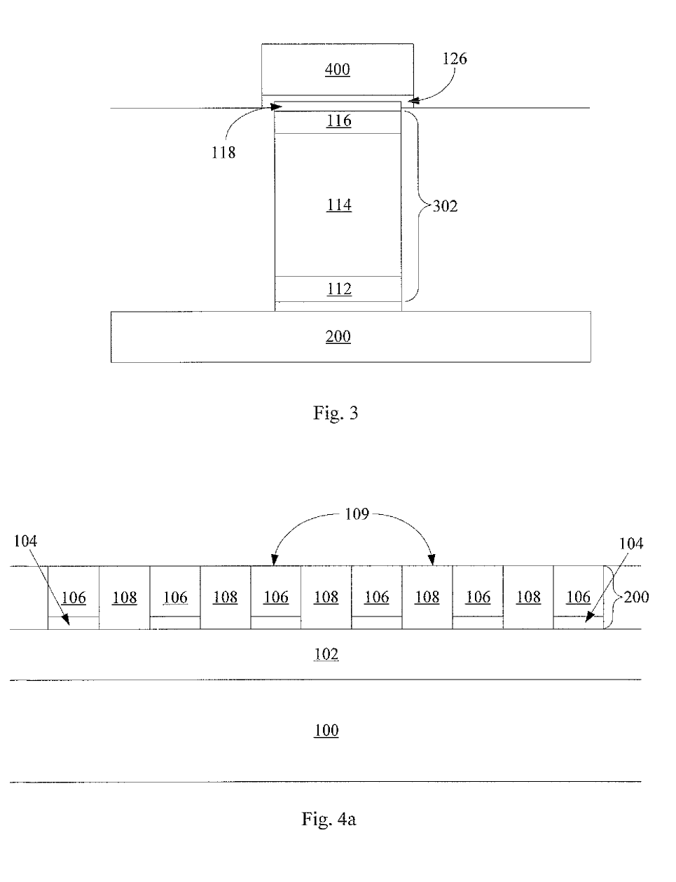

A preferred embodiment of the present invention is the memory cell shown in cross-section in FIG. 3. Diode 302 is vertically disposed between bottom conductor 200 and top conductor 400. In this example diode 302 is a vertically oriented p-i-n diode, comprising bottom heavily doped n-type region 112, middle intrinsic or lightly doped region 114, and top heavily doped p-type region 116. Clearly the polarity of the diode could be reversed; region 116 could be n-type while region 112 is p-type.

Silicide layer 118 is in contact with diode 302, in this example immediately on top of it. This silicide layer was preferably formed by depositing a silicide-forming metal, such as titanium, cobalt, or nickel, on the silicon and annealing to form the silicide. Layer 126, immediately above silicide layer 118, is a switching oxide layer. As will be described, layer 126 is preferably a grown oxide, most preferably thermally grown by exposing silicide layer 118 to an oxygen-containing ambient in elevated temperature. For example, a grown oxide may be formed by dry oxidation (i.e., exposing the silicide to an O₂ containing gas), wet oxidation (i.e., exposing the silicide to hot steam), plasma-enhanced oxidation (i.e., exposing the silicide to an oxygen plasma), chemical oxidation (i.e., exposing the silicide to an oxidizing liquid) and electrochemical oxidation (such as anodic oxidation). In contrast to a grown oxide layer, a deposited silicon oxide layer, for example, is formed on a surface by providing silicon and oxygen atoms to the surface; examples of deposition processes are chemical vapor deposition (CVD) or sputtering.

When the memory cell is formed, when a read voltage is applied between bottom conductor 200 and top conductor 400, very little current flows between them. Application of a set pulse between bottom conductor 200 and top conductor 400, across diode 302, silicide layer 118, and switching oxide layer 126, changes the resistivity of switching oxide layer 126. The set pulse is preferably applied with diode 302 under forward bias. After application of the set pulse, when the same read voltage is applied between bottom conductor 200 and top conductor 400, substantially more current flows between them. This higher-current state will be referred to as the set state, and may correspond to a data state of the cell.

Application of a reset pulse between bottom conductor 200 and top conductor 400 converts switching oxide layer 126 from its initial low-resistivity state to a higher-resistivity state. The reset pulse is preferably applied with diode 302 under reverse bias. This higher-resistivity state may correspond to a different data state of the memory cell. By applying additional set pulses and reset pulses, the memory cell can be reversibly switched between data states, serving as a rewriteable cell.

For simplicity, the example given describes two resistivity states. In other embodiments, there may be more than two reliably detectable resistivity states, which may correspond to more than two data states.

To summarize, the memory cell of FIG. 3 was formed by forming a vertically oriented diode; and thermally growing an oxide layer, wherein the diode and the grown oxide layer are disposed electrically in series between a first conductor and a second conductor, wherein the memory cell comprises the diode and the grown oxide, and wherein the grown oxide layer serves as a reversible switching element. In preferred embodiments the vertically oriented diode is formed by depositing the silicon, wherein at least some of the silicon is amorphous; forming a titanium or cobalt layer above the amorphous silicon; annealing to form a titanium silicide layer or a cobalt silicide layer and crystallize the amorphous silicon in contact with the silicide layer.

A detailed example will be provided describing fabrication of a first memory level in a monolithic three dimensional memory array comprising memory cells formed according to the present invention. It will be understood that this example is provided for illustration only, and that the present invention may take many other forms. In this example, many details will be provided, including specific steps, materials, and conditions. As will be appreciated by those skilled in the art, however, many of these details can be altered, augmented, or omitted while the results fall within the scope of the invention. The '030 patent described fabrication of a monolithic three dimensional memory array comprising memory cells like those of FIG. 1. Petti et al., U.S. Pat. No. 6,946,719, “Semiconductor Device Including Junction Diode Contacting Contact-Antifuse Unit Comprising Silicide,” hereby incorporated by reference, describes fabrication of a monolithic three dimensional memory array comprising a related memory cell. For clarity, not all of the details of these patents and earlier incorporated patent and applications will be included, but it will be understood that no teaching of these applications is intended to be excluded.

### EXAMPLE

Fabrication of a single memory level is described in detail. Additional memory levels can be stacked, each monolithically formed above the one below it.

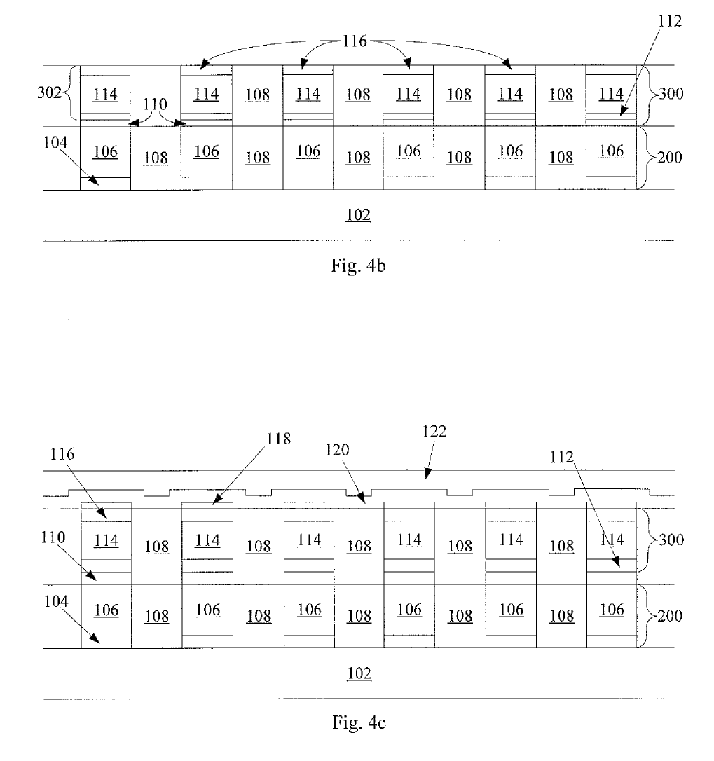

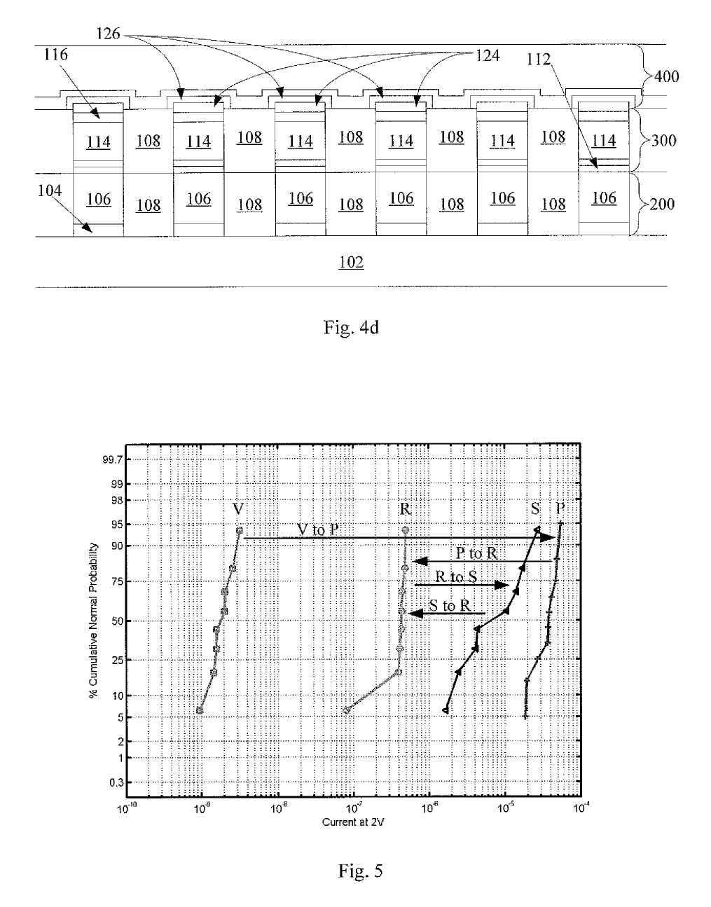

Turning to FIG. 4a, formation of the memory begins with a substrate 100. This substrate 100 can be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The semiconducting material can be a bulk wafer or silicon-on-insulator. The substrate may include integrated circuits fabricated therein.

An insulating layer 102 is formed over substrate 100. The insulating layer 102 can be silicon oxide, silicon nitride, high-dielectric film, Si—C—O—H film, or any other suitable insulating material.

The first conductors 200 are formed over the substrate 100 and insulator 102. An optional adhesion layer 104, preferably titanium nitride or some other appropriate material, is deposited first by any conventional method. The thickness of adhesion layer 104 can range from about 20 to about 500 angstroms, preferably about 200 angstroms.

The next layer to be deposited is conducting layer 106. Conducting layer 106 can comprise any suitable conducting material known in the art. Conducting layer 106 must survive temperature steps that in most embodiments will exceed 650 degrees C.; thus tungsten is preferred. Tungsten layer 106 can be deposited by any CVD process or a physical vapor deposition process. In one embodiment, the thickness of conducting layer 106 can range from about 200 to about 2500 angstroms. In another embodiment, the thickness of conducting layer 106 is about 1500 angstroms.

Layers 104 and 106 are patterned and etched using any suitable masking and etching process to form substantially parallel, substantially coplanar conductors 200, shown in FIG. 4a in cross-section. The width of conductor rails 200 after etch can range from about 300 to about 2500 angstroms. (In this discussion “width” will refer to the width of a line or feature measured in the plane substantially parallel to substrate 100.) The width of the gaps between conductor rails 200 preferably is substantially the same as the width of conductor rails 200 themselves, though it may be greater or less.

Next a dielectric material 108 is deposited over and between conductor rails 200. Dielectric material 108 can be any known electrically insulating material, such as silicon oxide, silicon nitride, or silicon oxynitride. In a preferred embodiment, silicon oxide is used as dielectric material 108. The silicon oxide can be deposited using any known process, such as CVD, or, for example, high density plasma CVD (HDPCVD).

Finally, excess dielectric material 108 on top of conductor rails 200 is removed, exposing the tops of conductor rails 200 separated by dielectric material 108, and leaving a substantially planar surface 109. The resulting structure is shown in FIG. 4a. This removal of dielectric overfill to form planar surface 109 can be performed by any process known in the art, such as chemical mechanical planarization (CMP) or etchback. For example, the etchback techniques described in Raghuram et al., U.S. application Ser. No. 10/883,417, “Nonselective Unpatterned Etchback to Expose Buried Patterned Features,” filed Jun. 30, 2004 and hereby incorporated by reference in its entirety, can advantageously be used. Alternatively, conductor rails can be formed by a Damascene process.

Next, turning to FIG. 4b, vertical semiconductor pillars will be formed above completed conductor rails 200. (To save space substrate 100 is omitted in FIG. 4b and subsequent figures.) In preferred embodiments, barrier layer 110, preferably of titanium nitride, is deposited as the first layer after planarization of the conductor rails. Its thickness can be, for example, about 20 to about 500 angstroms. The thickness of barrier layer 110 is preferably about 200 angstroms.

Next semiconductor material that will be patterned into pillars is deposited. The semiconductor material is preferably silicon or a silicon alloy such as silicon-germanium. For simplicity, this description will refer to the semiconductor material as silicon, but it will be understood that other materials may be substituted.

In preferred embodiments, the semiconductor pillar is a junction diode, comprising a bottom heavily doped region of a first conductivity type and a top heavily doped region of a second conductivity type. The middle region can intentionally be lightly doped, or it can be intrinsic, or not intentionally doped. An undoped region will never be perfectly electrically neutral, and will always have defects or contaminants that cause it to behave as if slightly n-doped or p-doped. Such a diode can be considered a p-i-n diode. In the present example, a diode will be described having a heavily doped n-type bottom region, an intrinsic middle region, and a heavily doped p-type top region.

The term junction diode is used herein to refer to a semiconductor device with the property of conducting current more easily in one direction than the other, having two terminal electrodes, and made of semiconducting material which is p-type at one electrode and n-type at the other. Examples include p-n diodes, which have p-type semiconductor material and n-type semiconductor material in contact, and p-i-n diodes, in which intrinsic (undoped) or lightly doped semiconductor material is interposed between p-type semiconductor material and n-type semiconductor material.

Heavily doped n-type silicon region 112 is preferably doped in situ by flowing a donor gas providing atoms of an n-type dopant, preferably phosphorus, during deposition of the silicon. In a preferred embodiment, this layer can range from about 100 to about 1000 angstroms, preferably about 200 angstroms.

The next layer 114 is preferable intrinsic silicon. This layer can formed by any deposition method known in the art. The thickness of lightly doped n-type silicon layer 114 can range from about 1000 to about 4800 angstroms, preferably about 3300 angstroms. In one embodiment, silicon is deposited without intentional doping, yet has defects which cause it to behave as though slightly n-type. Regions 112 and 114 are preferably amorphous as deposited.

Semiconductor layers 114 and 112 just deposited will be patterned and etched to form semiconductor pillars 300, along with barrier layer 110. Semiconductor pillars 300 should have about the same pitch and about the same width as conductors 200 below, such that each semiconductor pillar 300 is formed on top of a conductor 200. Some misalignment can be tolerated.

The semiconductor pillars 300 can be formed using any suitable masking and etching process. For example, photoresist can be deposited, patterned using standard photolithography techniques, and etched, then the photoresist removed. Alternatively, a hard mask of some other material, for example silicon dioxide, can be formed on top of the semiconductor layer stack, with bottom antireflective coating (BARC) on top, then patterned and etched. Similarly, dielectric antireflective coating (DARC) can be used as a hard mask.

The photolithography techniques described in Chen, U.S. Pat. No. 7,172,840, “Photomask Features with Interior Nonprinting Window Using Alternating Phase Shifting”; or Chen, U.S. application Ser. No. 10/815,312, Photomask Features with Chromeless Nonprinting Phase Shifting Window,” filed Apr. 1, 2004, both owned by the assignee of the present invention and hereby incorporated by reference, can advantageously be used to perform any photolithography step used in formation of a memory array according to the present invention.

Dielectric material 108 is deposited over and between the semiconductor pillars 300, filling the gaps between them. Next the dielectric material 108 on top of the pillars 300 is removed, exposing the tops of pillars 300 separated by dielectric material 108, and leaving a substantially planar surface. This removal of dielectric overfill can be performed by any process known in the art, such as CMP or etchback. The resulting structure is shown in FIG. 4b. An ion implantation step forms top heavily doped p-type regions 116, completing p-i-n diodes 302. Any appropriate p-type dopant, for example boron, may be used.

Turning to FIG. 4c, an optional oxide, nitride, or oxynitride layer 118 is formed on heavily doped regions 116. In some embodiments, as shown, a silicon dioxide layer 118 is grown by oxidizing silicon at the tops of heavily doped regions 116 at about 600 to about 850 degrees C. for about 20 seconds to about two minutes, forming between about 15 and about 50 angstroms of silicon dioxide. Layer 118 could be deposited instead. In other embodiments, layer 118 is omitted.

Next a layer 120 of a silicide-forming metal is deposited. Preferred silicide-forming metals to be used for this purpose include titanium, cobalt, chromium, tantalum, platinum, nickel, niobium, and palladium. Titanium and cobalt are preferred. This example will describe the use of titanium for layer 120, but it will be understood that any of the other materials can be used.

Titanium layer 120 is deposited to any suitable thickness, for example between about 60 and about 200 angstroms, preferably between about 100 and about 150 angstroms, most preferably about 100 angstroms. To prevent oxidation of titanium layer 120, titanium nitride layer 122 is deposited on titanium layer 120, preferably about 300 angstroms thick. Layers 120 and 122 can be deposited by any conventional method, for example by sputtering.

An anneal is performed between about 600 and about 800 degrees from about 10 seconds to about two minutes, preferably between about 650 degrees and about 750 degrees, most preferably at about 670 degrees for about 20 seconds, for example in nitrogen. The anneal serves to react titanium layer 120 with heavily doped regions 116 where it overlies them to form titanium silicide. If optional oxide layer 118 was formed, it is substantially entirely reduced between titanium layer 120 and the silicon of heavily doped region 116. This anneal step will generally also serve to crystallize the silicon of heavily doped n-type region 112, intrinsic region 114, heavily dope p-type region 116. Recall that these regions were amorphous as deposited.

Turning to FIG. 4d, as in a conventional salicide process, titanium nitride layer 122 and unreacted titanium 120 are stripped in a selective wet etch, leaving behind titanium silicide layers 124, each formed in a disk-shaped region on the top of one of the silicon pillars 300. Note that some thickness of top heavily doped p-type region 116 is consumed in formation of titanium silicide layer 124.

Conventional salicide formation includes a second anneal following strip of the unreacted titanium to convert the titanium silicide from the high-resistivity C49 phase to the low-resistivity C54 phase. In embodiments of the present invention this step is omitted.

Switching oxide layer 126 is formed on titanium silicide layer 124, preferably by oxidation of titanium silicide layer 124. Oxidation is performed between about 600 and about 850 degrees for between about 20 seconds to about two minutes, preferably at about 775 degrees for about two minutes. The resulting oxide layer 126 will be primarily silicon dioxide, though some amount of titanium or titanium oxide may be included in switching oxide layer 126. Similarly, if cobalt was used for layer 120 in place of titanium, the resulting oxide layer 126 will be primarily silicon dioxide, though some amount of cobalt or cobalt oxide may be included.

Note that in this example the silicide reaction forming titanium silicide layer 124 and the crystallization of silicon regions 112, 114, and 116 are performed in a single anneal step. Titanium silicide begins to form at a temperature lower than that at which large-scale crystallization of silicon begins, however. Thus when silicide layer 124 begins to form, silicon regions 112, 114, and 116 are still largely amorphous, and this amorphous silicon crystallizes in contact with titanium silicide layer 124.

Overlying conductors 400 can be formed in the same manner as underlying conductors 200. Overlying conductors 400 will be formed at a height above the height of underlying conductors 200, and extend in a different direction from them, preferably substantially perpendicular to them. The resulting structure is a bottom or first level of memory cells. Additional memory levels can be monolithically formed above the first, as described in the '030 patent and the other incorporated references, forming a monolithic three dimensional memory array. For example, a second plurality of pillars can be formed above the upper conductors, and a third plurality of conductors can be formed above them. The upper conductors of one memory level can serve as the lower conductors of an overlying memory level, or an interlevel dielectric can be formed between them.

To summarize, a monolithic three dimensional memory level can be formed by a) monolithically forming a first memory level above a substrate by a method comprising: i) forming a plurality of bottom conductors; ii) forming a plurality of top conductors; iii) forming a plurality of vertically oriented diodes; and iv) growing a plurality of oxide layers, wherein the first memory level comprises a first plurality of memory cells, wherein each memory cell comprises one of the diodes and one of the grown oxide layers disposed electrically in series between one of the bottom conductors and one of the top conductors, wherein, for each memory cell, the grown oxide layer serves as a reversible switching element; and b) monolithically forming a second memory level above the first.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

### Set and Reset

As described earlier, the switching oxide layer 126 of FIG. 3, which in preferred embodiments is a grown oxide layer, is generally insulating as formed, such that when a read voltage is applied between bottom conductor 200 and top conductor 400, little or no current flows between these conductors. When a set pulse is applied, switching oxide layer 126 becomes lower resistivity. When the same read voltage is applied between bottom conductor 200 and top conductor 400, substantially more current flows. A subsequent reset pulse increases the resistivity of switching oxide layer 126, such that less current flows when a read voltage is applied.

In general, it is believed that the set transition, from high-resistivity to low-resistivity, is voltage-based, and is achieved by applying sufficient voltage across switching oxide layer 126. In contrast, it is believed that the reset transition, from low-resistivity to high-resistivity, is current-based, and is achieved when sufficient current flows across switching oxide layer 126.

The set transition is preferably achieved by applying a set voltage between bottom conductor 200 and top conductor 400 of FIG. 3 such that diode 302 is forward biased. In general, switching oxide layer 126 undergoes the set transition, from high resistivity to low resistivity, at a voltage of about 2-3 volts across the oxide layer. (An additional voltage will be across the diode, so the voltage between bottom conductor 200 and top conductor 400 will be higher than 2-3 volts.) At this voltage, once switching oxide layer 126 has switched to the set state, in general the current isn't high enough to cause reset, and switching oxide layer 126 remains in the set state, as intended.

A problem may arise when an attempt is made to reset switching oxide layer 126 with the diode under forward bias. Switching oxide layer 126 is in the low-resistivity state. Recall that the reset transition is current-based; thus a relatively high current (in one example, about 100 to about 200 microamps) is required to cause reset to take place. In forward bias, a relatively high voltage, for example about eight volts, must be applied between conductors 200 and 400 to achieve this reset current. As in any circuit, current is the same in all elements of the circuit, including both switching oxide layer 126 and diode 302. Voltage, however, is distributed between these elements. After switching (after the reset transition is achieved, and switching oxide layer 126 has become high-resistivity), most of the voltage is across switching oxide 126 rather than across the diode. This relatively high voltage may be sufficient to immediately cause switching oxide 126 to undergo an unwanted set conversion, back to the low-resistivity state from which it was just switched. Thus with the diode in forward bias, it may be difficult to cause switching oxide 126 to remain in the reset state.

Instead, suppose the reset transition is performed with the diode under reverse bias. Again, switching oxide layer 126 is in the low-resistivity state. Voltage is increased between bottom conductor 200 and top conductor 400 until sufficient current flows across switching oxide layer 126 to cause it to reset; in one example this is about −13 volts. After reset, because the diode is under reverse bias, most of the voltage is across the diode, not across switching oxide layer 126. The relatively low voltage across switching oxide layer 126 avoids the tendency for it to spontaneously undergo an unwanted set transition after reset.

Thus it is preferred to perform the set transition with diode forward-biased and the reset transition with the diode reverse-biased. As described in Kumar et al., U.S. patent application Ser. No. 11/496,986, “Method For Using A Memory Cell Comprising Switchable Semiconductor Memory Element With Trimmable Resistance,” filed Jul. 31, 2006, and hereby incorporated by reference, performing the reset transition with the diode in reverse bias has the additional advantage of reducing leakage current across unselected memory cells in the array.

When the memory cell is initially formed, switching oxide layer 126 is in its initial high-resistivity state. FIG. 5, is a probability plot showing read current at about 2 volts for memory cells according to the present invention. Referring FIG. 5, this initial state of the memory cell will be referred to as the V state. In one example, under a read voltage of about 2 volts, the current between conductors 200 and 400 is about 1 nanoamp or less, or a few nanoamps.

After application of a first set pulse, preferably having voltage between about 5 and about 8 volts, the memory cell is converted to a second state, which will be referred to as the P state. The set voltage is preferably positive; i.e. the diode is under forward bias. Switching oxide layer 126 undergoes a set transition; i.e. it is converted from the initial high-resistivity state to a lower-resistivity state, indicated in FIG. 5 by the arrow labeled “V to P”. At an applied read voltage of about 2 volts, current between conductors 200 and 400 when the memory cell is in the P state is on the order of tens of microamps. After application of a first reset pulse, preferably having voltage of about −13 volts, the memory cell is converted to a third state, which will be referred to as the R state. The reset voltage is preferably negative; i.e. the diode is under reverse bias. Switching oxide layer 126 undergoes a reset transition; i.e. it is converted from a lower-resistivity state to a higher-resistivity state, transition “P to R” in FIG. 5. At an applied read voltage of about 2 volts, current between conductors 200 and 400 when the memory cell is in the R state is hundreds of nanoamps.

After application of a second set pulse, preferably having voltage of about 5 to about 8 volts, the memory cell is converted to a fourth state, which will be referred to as the S state. The set voltage again is preferably positive, with the diode under forward bias. Switching oxide layer 126 is converted from a higher-resistivity state to a lower-resistivity state; this transition is “R to S” in FIG. 5. At an applied read voltage of about 2 volts, current between conductors 200 and 400 when the memory cell is in the S state is a few microamps.

In this example, the initial cell state V was the lowest-current state, while the second cell state P was the highest-current state. It was found, in one embodiment, that it can be difficult to return to either of these states. Reset transitions put the cell in the R state, a lower-current state with current of hundreds of nanoamps, but did not return it to the initial V state, with current of a few nanoamps. Similarly, the first set transition put the cell into the P state, having current of tens of microamps, while subsequent set transitions put the cell in the S state, having current of only a few microamps, but did not return it to the higher current of the P state. It proved possible to repeatably and reliably switch between the R and S states, however.

Thus in one embodiment, such a cell could serve as a rewriteable cell which is repeatably switched between the R and the S states, each of which corresponds to a data state. In this embodiment, the “R to S” and “S to R” transitions of FIG. 5 are repeated each time the cell is written or erased. In such a cell, it may be desirable not to use the V and the P states as data states, and to apply the first set and reset pulses before the memory cell reaches the end user.

In an alternative embodiment, such a cell could serve as a one-time-programmable cell having four data states corresponding to the V, P, R, and S states. In some instances, the current ranges of the S state and the P state were undesirably close. In this case, the memory cell could be treated as a one-time programmable cell having three states, the V state, the P state, and the R state.

In alternative embodiments, a rewriteable memory cell formed according to embodiments of the present invention may have three or more data states. Similarly, a one-time programmable cell formed according to embodiments of the present invention may have five or more data states.

As described, it is believed that crystallizing the silicon of diode 302 adjacent to silicide layer 124 causes diode 302 to be formed of polysilicon which is low-defect and low-resistivity as formed, and that this polysilicon does not change in resistivity. It is believed that the change in current between the V, P, R, and S states of the memory cell is due to changes in the resistivity of switching oxide 126.

It may be, however, that some degree of resistivity switching takes place in the polysilicon that makes up diode 302 as well as in switching oxide layer 126, as described in Kumar et al., earlier incorporated.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A method for forming a rewriteable memory cell, the method comprising:
forming a vertically oriented diode; and
thermally growing an oxide layer,
wherein the diode and the grown oxide layer are disposed electrically in series between a first conductor and a second conductor,
wherein the memory cell comprises the diode and the grown oxide, and
wherein the grown oxide layer serves as a reversible switching element.

2. The method of claim 1 wherein the diode is a semiconductor junction diode comprising silicon.

3. The method of claim 2 wherein the diode is a p-i-n diode.

4. The method of claim 2 wherein the step of forming the vertically oriented diode comprises:
depositing the silicon, wherein at least some of the silicon is amorphous;
forming a titanium or cobalt layer above the amorphous silicon;
annealing to form a titanium silicide layer or a cobalt silicide layer and crystallize the amorphous silicon in contact with the silicide layer.

5. The method of claim 4 wherein the step of thermally growing the oxide layer comprises growing an oxide layer on the silicide layer by heating the exposed silicide layer in an oxygen-containing ambient.

6. The method of claim 4 wherein the step of forming the vertically oriented diode comprises patterning the amorphous silicon in the form of a pillar.

7. The method of claim 6 wherein the step of forming a silicide layer in contact with the amorphous silicon comprises:
depositing titanium or cobalt above the amorphous silicon;
reacting the titanium or cobalt with the amorphous silicon to form the silicide layer; and
etching to remove the unreacted titanium or cobalt.

8. The method of claim 7 wherein an oxide or oxynitride layer is disposed between the amorphous silicon and the titanium or cobalt, and wherein the oxide or oxynitride layer is fully reduced during the reacting step.

9. The method of claim 1 wherein the grown oxide layer has an initial resistivity,
wherein a first set pulse is applied between the first conductor and the second conductor, and
wherein, after application of the first set pulse, the grown oxide layer has a second resistivity, the second resistivity lower than the initial resistivity.

10. The method of claim 9
wherein, after application of the first set pulse, a first reset pulse is applied between the first conductor and the second conductor, and
wherein, after application of the first reset pulse, the grown oxide layer has a third resistivity, the third resistivity higher than the second resistivity.

11. The method of claim 10 wherein during application of the first set pulse the diode is under forward bias.

12. The method of claim 11 wherein during application of the first reset pulse the diode is under reverse bias.

13. The method of claim 1 wherein the grown oxide is silicon dioxide.

14. A method for forming a monolithic three dimensional memory array, the method comprising:
a) monolithically forming a first memory level above a substrate by a method comprising:
i) forming a plurality of bottom conductors;
ii) forming a plurality of top conductors;
iii) forming a plurality of vertically oriented diodes; and
iv) growing a plurality of oxide layers,
wherein the first memory level comprises a first plurality of memory cells,
wherein each memory cell comprises one of the diodes and one of the grown oxide layers disposed electrically in series between one of the bottom conductors and one of the top conductors,
wherein, for each memory cell, the grown oxide layer serves as a reversible switching element; and
b) monolithically forming a second memory level above the first.

15. The method of claim 14 wherein each of the diodes is a semiconductor junction diode comprising silicon.

16. The method of claim 15 wherein each of the diodes is a p-i-n diode.

17. The method of claim 15 wherein the step of forming the plurality of vertically oriented diodes comprises:
depositing the silicon, wherein at least some of the silicon is amorphous;
depositing titanium or cobalt in contact with the amorphous silicon;
annealing to form a plurality of titanium silicide layers or cobalt silicide layers and to crystallize the amorphous silicon in contact with the silicide layers.

18. The method of claim 17 wherein the step of thermally growing the plurality of oxide layers comprises growing the plurality of oxide layers on the plurality of silicide layers by heating the exposed silicide layers in an oxygen-containing ambient.

19. The method of claim 14 wherein the first memory level comprises a first memory cell, the first memory cell comprising a first grown oxide layer and a first diode disposed between a first bottom conductor and a first top conductor,
wherein the first grown oxide layer has an initial resistivity,
wherein a first set pulse is applied between the first top conductor and the first bottom conductor, and
wherein, after application of the first set pulse, the first grown oxide layer has a second resistivity, the second resistivity lower than the initial resistivity.

20. The method of claim 19
wherein, after application of the first set pulse, a first reset pulse is applied between the first bottom conductor and the first top conductor, and
wherein, after application of the first reset pulse, the first grown oxide layer has a third resistivity, the third resistivity higher than the second resistivity.

21. The method of claim 14 wherein the plurality of grown oxides comprise silicon dioxide.

22. The method of claim 14 wherein the substrate comprises monocrystalline silicon.
